(19) United States
(12) Patent Application Publication
(10) Pub. No.: US 2009/0219690 A1
(43) Pub. Date: Sep. 3, 2009

(54) Heat sink capable of external deflection

(75) Inventors: Shih-Chih Lin, Taipei County (TW); De-Cheng Luo, Sicchuan (CN)

Correspondence Address: BACON & THOMAS, PLLC, 625 SLATERS LANE, FOURTH FLOOR, ALEXANDRIA, VA, 22314-1176, US

(73) Assignee: TAI-SOL ELECTRONICS CO., LTD., TAIPEI CITY (TW)

(21) Appl. No.: 12/081,061

(22) Filed: Apr. 10, 2008

(30) Foreign Application Priority Data
Mar. 3, 2008 (TW) 97203583

(51) Int. Cl. H05K 7/20

(52) U.S. Cl. 361/697

(57) ABSTRACT

A heat sink capable of external deflection includes a heat-dissipating member, a cooling fan, and a deflector. The heat-dissipating member includes an entrance side and an exit side. The cooling fan is mounted at the entrance side of the heat-dissipating member. The deflector includes at least one inlet, at least one outlet, and at least one passage in communication with the at least one inlet and outlet. The deflector is mounted to the heat-dissipating member in such a way that each of the at least one inlet is close to the entrance side, each of the at lease one passage extends to an external side of said exit side, and each of the at least one outlet faces a lower side of the heat-dissipating member. Therefore, the heat sink attains relatively larger heat-dissipating range and relatively higher heat-dissipating efficiency on the whole.

### BACKGROUND OF THE INVENTION

1. Field of the Invention

The present invention relates generally to heat sinks, and more particularly, to a heat sink capable of external deflection.

2. Description of the Related Art

General electronic components generate high heat in operation and if the temperature of the electronic components is too high, the electronic product having the overheated electronic components will fail to function normally. Thus, the general electronic product is provided with a heat sink for keeping the electronic components working in stable operating temperature.

A general heat sink includes a bottom plate, a fin set mounted to the bottom plate, and a cooling fan mounted to the fin set. The bottom plate is mounted to an electronic component in need of thermal dissipation, such that the heat generated by the electronic component can be transferred to the bottom plate and the fin set. When the cooling fan is operated, the airstream is generated to take the heat away from the fin set, thus thermally dissipating the electronic component.

However, the efficiency of thermal dissipation has been required higher and higher and thus the above-mentioned heat sink becomes relatively larger and larger. When the heat sink is mounted to the electronic component in need of thermal dissipation, the heat sink structurally interferes with the thermal dissipation of other electronic components located around that one and the heat sink, such that the whole heat-dissipating area becomes smaller and the overall efficiency of the thermal dissipation becomes lower.

### SUMMARY OF THE INVENTION

The primary objective of the present invention is to provide a heat sink capable of external deflection, whose heat-dissipating range is relatively larger and whose overall heat-dissipating efficiency is relatively higher.

The foregoing objective of the present invention is attained by the heat sink composed of a heat-dissipating member, a cooling fan, and a deflector. The heat-dissipating member includes an entrance side and an exit side. The cooling fan is mounted at the entrance side of the heat-dissipating member. The deflector includes at least one inlet, at least one outlet, and at least one passage in communication with the at least one inlet and outlet. The deflector is mounted to the heat-dissipating member in such a way that each of the at least one inlet is close to the entrance side, each of the at lease one passage extends to an external side of said exit side, and each of the at least one outlet faces a lower side of the heat-dissipating member.

### BRIEF DESCRIPTION OF THE DRAWINGS

FIG. 1 is an elevation view of a first preferred embodiment of the present invention.

FIG. 2 is a side view of the first preferred embodiment of the present invention.

FIG. 3 is a rear view of the first preferred embodiment of the present invention.

FIG. 4 is an exploded view of the first preferred embodiment of the present invention.

FIG. 5 is an exploded view of a part of the first preferred embodiment of the present invention, illustrating the structure of the deflector.

FIG. 6 is another exploded view of a part of the first preferred embodiment of the present invention, illustrating the structure of the deflector.

FIG. 7 is a perspective view of the first preferred embodiment of the present invention applied to a motherboard.

FIG. 8 is an exploded view of a part of a second preferred embodiment of the present invention, illustrating the structure of the deflector.

FIG. 9 is another exploded view of a part of the second preferred embodiment of the present invention, illustrating the structure of the deflector.

FIG. 10 is a perspective view of the second preferred embodiment of the present invention applied to a motherboard.

### DETAILED DESCRIPTION OF PREFERRED EMBODIMENTS

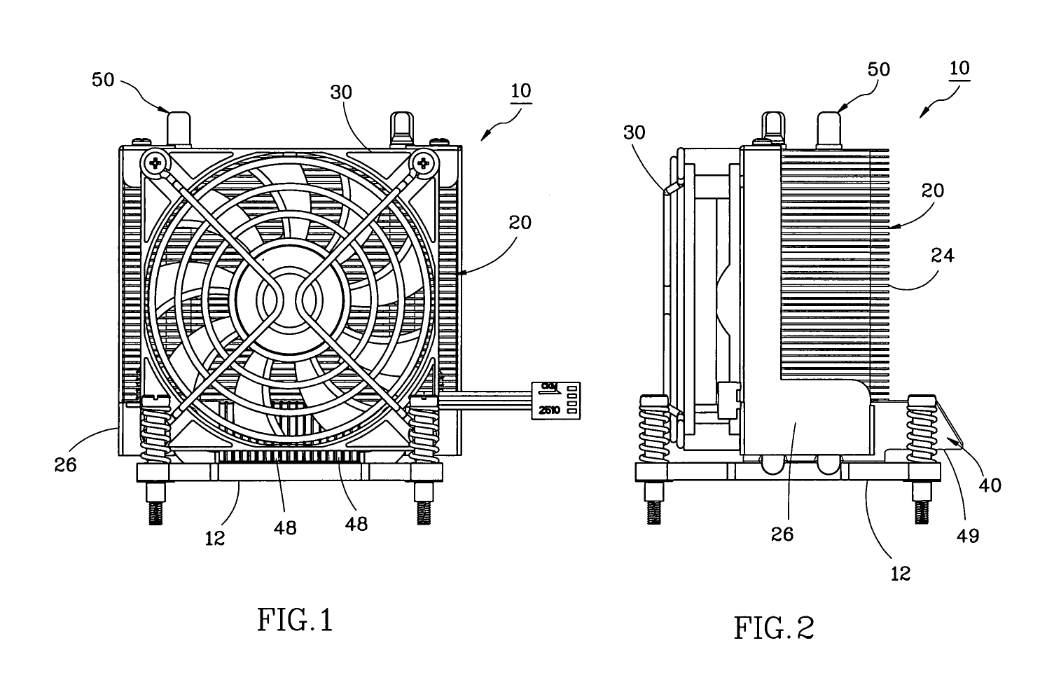

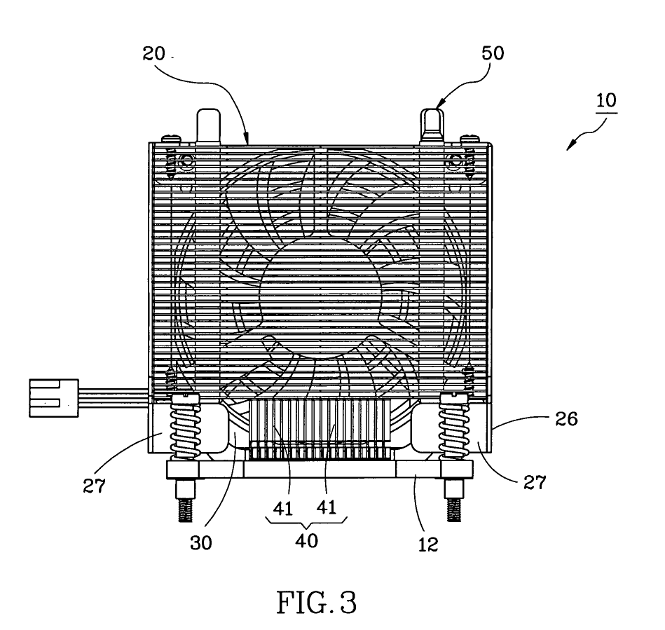

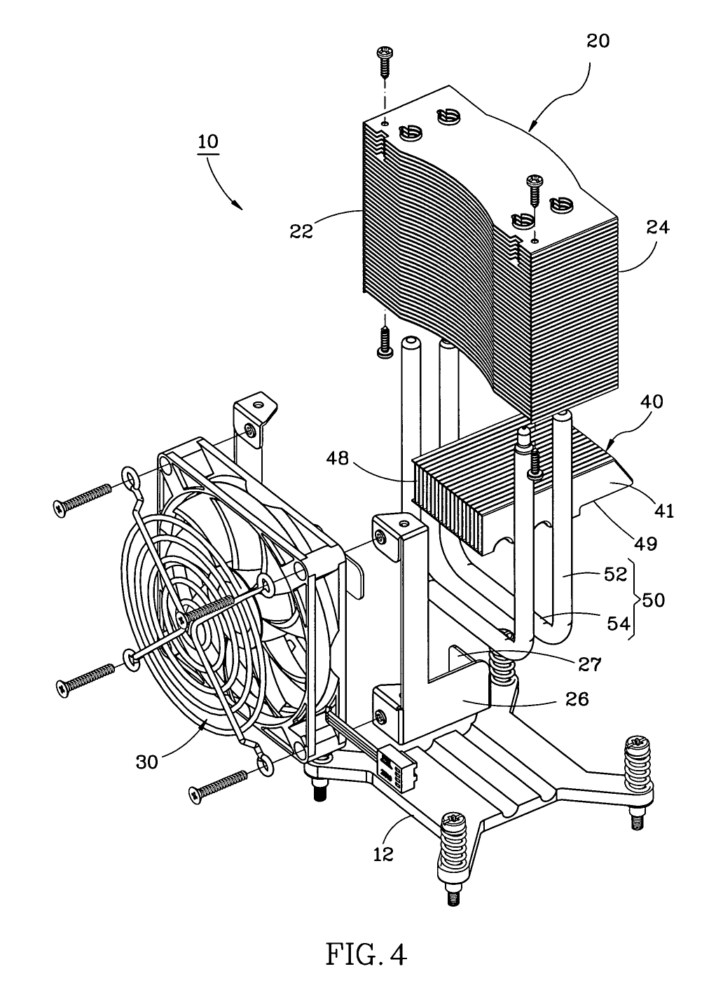

Referring to FIGS. 1-4, a heat sink 10 capable of external deflection in accordance with a first preferred embodiment of the present invention is composed of a bottom plate 12, a heat-dissipating member 20, a cooling fan 30, and a deflector 40. Each of the bottom plate 12 and the heat-dissipating member 20 is made of heat-conductive material. The heat-dissipating member 20 includes a plurality of fins parallel spaced from one another, defining an entrance side 22 and an exit side 24.

The cooling fan 30 and the heat-dissipating member 20 are connected with each other via a strut 26. The cooling fan 30 is located at the entrance side 22 for generating and driving the airstream to pass through the heat-dissipating member 20 from the entrance side 22 to the exit side 24. The strut 26 has a rear retaining member 27 located below the exit side 24 for forcing a part of the airstream flowing to the exit side 24 to flow toward a lower side of the heat-dissipating member 20, thus effecting the wind deflection.

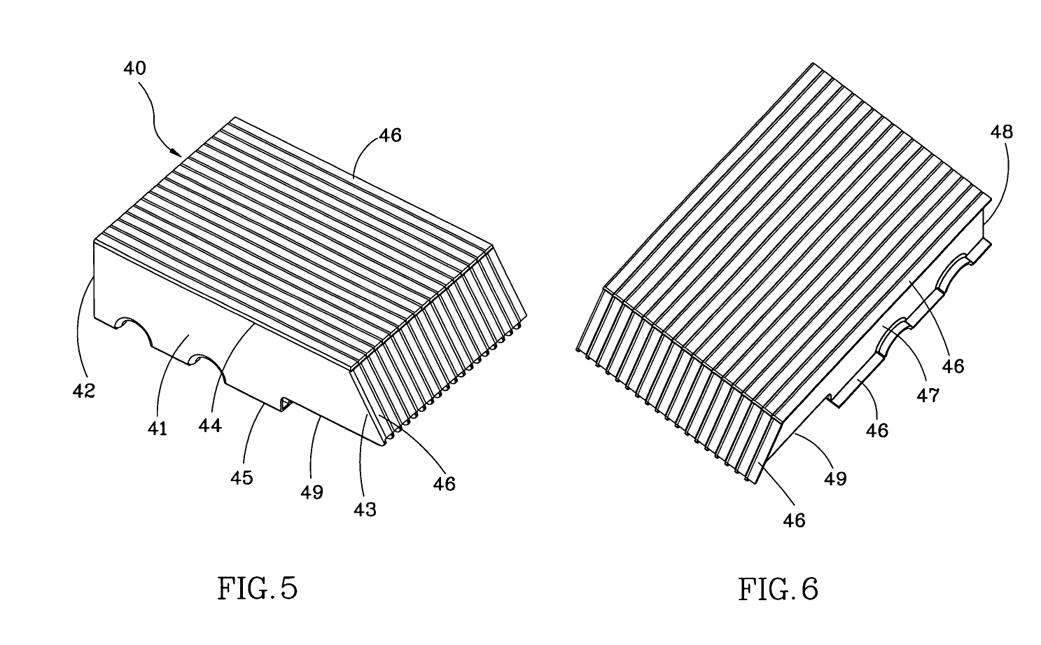

Referring to FIGS. 5 and 6, the deflector 40 includes a plurality of fin-shaped base members 41. Each of the fin-shaped base members 41 has a first short side 42, a second short side 43, a first long side 44, and a second long side 45. A stopper 46 is mounted on each of the adjacent first long and second short sides 44 and 43 and on where each of the second long sides 45 is close to the first short side 42. The fin-shaped base members 41 of the deflector 40 are combined in a way of being parallel spaced from one another, such that the stoppers 46 are apposed one another at a top side of the deflector 40 and a part of a bottom side of the same. A passage 47 is formed between each two adjacent base members 41, defining an inlet 48 and an outlet 49. Each of the inlets 48 is located at the first short side 42 of the base member 41. Each of the outlets 49 is located at where the second long side 45 is close to the second short side 43. The deflector 40 is mounted between the base plate 12 and a bottom side of the heat-dissipating member 20. Each of the inlets 48 is close to the entrance side 22. Each of the passages 47 extends to an external side of the exit side 24, such that each of the outlets 49 faces the bottom plate 12. Two heat pipes 50 are mounted between the heat-dissipating member 20 and the deflector 40, each having two penetrative sections 52 and an intermediate section 54 located between the two penetrative sections 52. The two penetrative sections 52 are mounted to the heat-dissipating member 20 in a way of passing by two sides of the deflector 40. The intermediate section 54 is located between the heat-dissipating member 20 and the bottom plate 12 for enhancing the overall heat-dissipating efficiency of the heat sink 10.

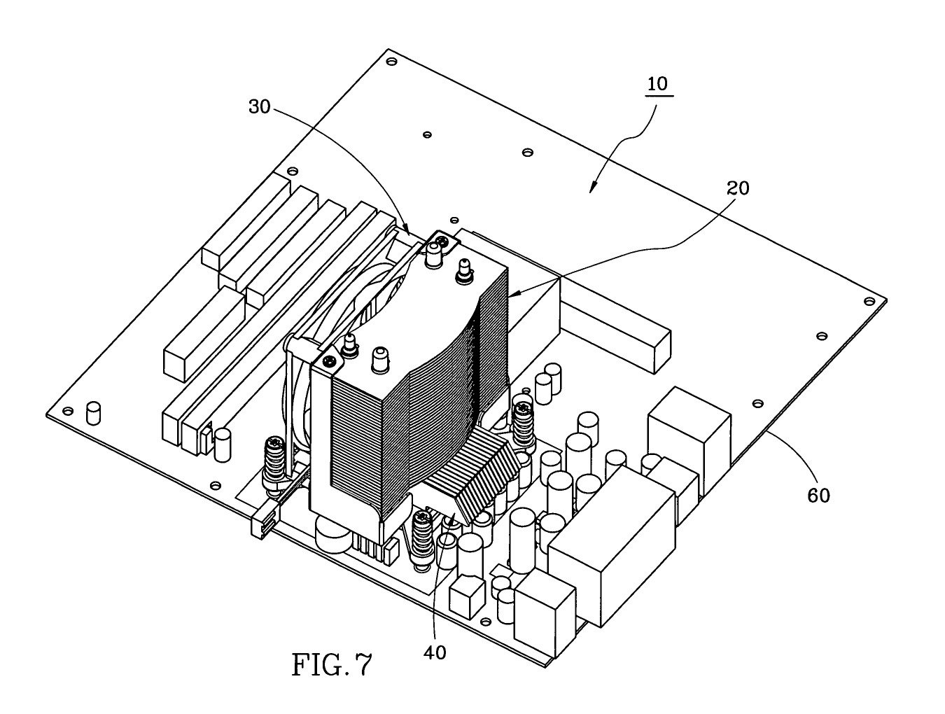

Referring to FIG. 7, when the heat sink 10 is mounted to a motherboard 60, the bottom plate 12 contacts against a surface of a central processing unit (CPU). High heat generated by the CPU in operation can be dissipated outside in such a way that the bottom plate 12 is thermally conductive and the airstream generated by the cooling fan 30 in operation flows through the heat-dissipating member 20. The airstream of the cooling fan 30 is guided into each of the inlets 48 of the deflector 40, in addition to the heat-dissipating member 20, and then flows through each of the passages 47 to each of the outlets 49. In this way, the airstream can flow out of the surface of the motherboard 60 and right toward electronic components around the CPU to take high heat generated by those electronic components to the external environment, thus effecting the thermal dissipation on the whole.

In addition, the deflector of the present invention can be interchanged by an alternative element as recited below.

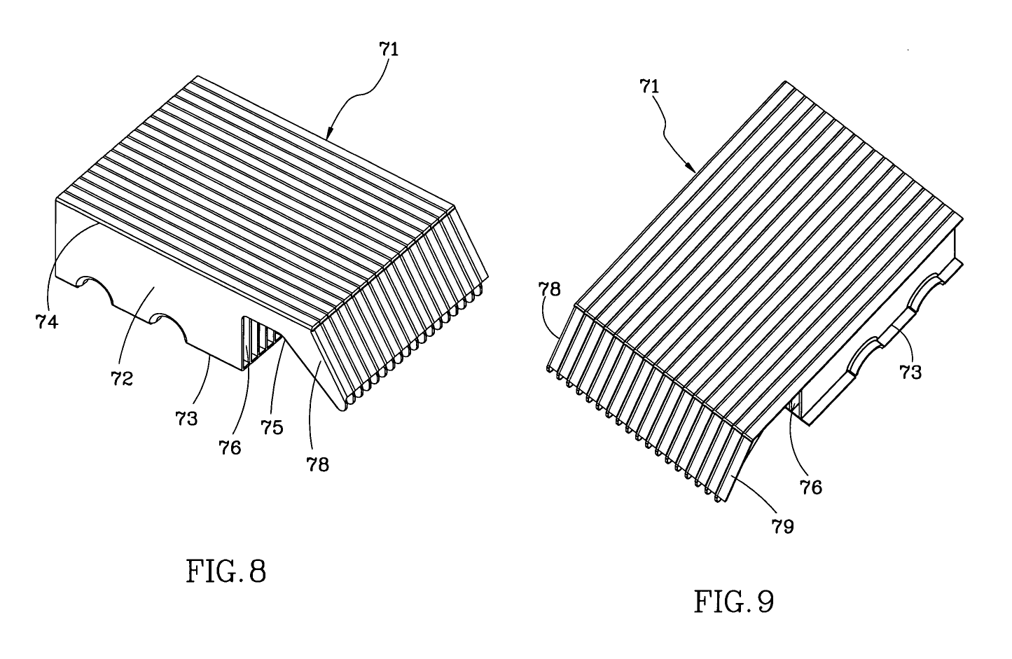

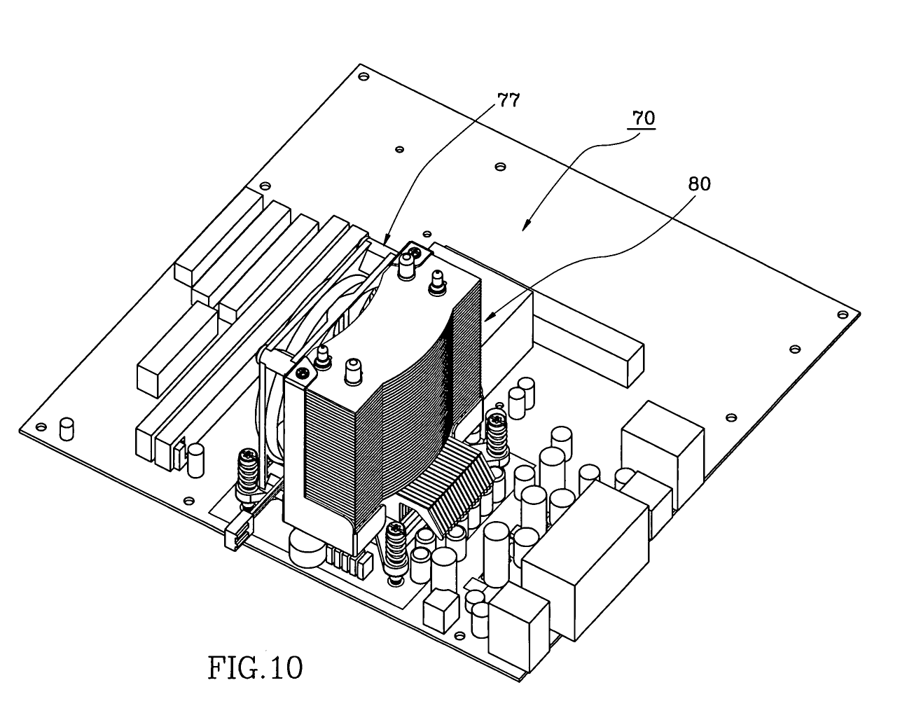

Referring to FIGS. 8-10, a heat sink 70 capable of external deflection in accordance with a second preferred embodiment of the present invention is similar to the heat sink 10 of the first embodiment, having the following difference. Each of the base members 72 of the deflector 71 includes a hollowed portion 75 recessed toward the first long side 74 from the second long side 73, such that the outlets 76 of the deflector 71 are located at the hollowed portions 75. When the airstream generated by the cooling fan 77 flows out of the outlets 76, the airstream can be interfered by the stoppers 79 at the second short sides 78 and then cooperate with the hollowed portions 75 to generate greater wind resistance. In this way, the airstream flows closer to an internal side of the heat-dissipating member 80 to also thermally dissipate electronic components closest to the periphery of the heat sink 70.

Although the present invention has been described with respect to specific preferred embodiments thereof, it is no way limited to the details of the illustrated structures but changes and modifications may be made within the scope of the appended claims.

What is claimed is:

1. A heat sink capable of external deflection, comprising:
a heat-dissipating member having an entrance side and an exit side;
a cooling fan mounted to said entrance side; and
a deflector having at least one inlet, at least one outlet, and at least one passage in communication with each of said at least one outlet and inlet, said deflector being mounted to said heat-dissipating member to enable each of said at least one inlet to be close to said entrance side, each of said at least one passage extending to an external side of said exit side, each of said at least one outlet facing a lower side of said heat-dissipating member.

2. The heat sink as defined in claim 1, wherein said deflector is composed of a plurality of fins and comprises at least two base members, each of said base members has a first short side, a second short side, a first long side, and a second long side, said first long side abutting said second short side, a stopper being mounted to each of said adjacent first long and second short sides and to where said second long side is close to said first short side, each of said base members being parallel spaced from each other, whereby said stoppers are apposed one another, said passage is located between each said two base members, said inlet is located at each of said first short sides, and each of said outlets is located where said second long side is close to said second short side.

3. The heat sink as defined in claim 1 further comprising at least one heat pipe, wherein each of said at least one heat pipe has two penetrative sections and an intermediate section located between said two penetrative sections, said two penetrative sections being mounted to said heat-dissipating member in a way of passing by two sides of said deflector, said intermediate section being mounted to said heat-dissipating member.

4. The heat sink as defined in claim 1 further comprising a strut, wherein said strut has a rear retaining member, and said heat-dissipating member and said cooling fan are mounted to said strut in such a way that said cooling fan is located at said entrance side and said rear retaining member is located below said exit side.
